(19) United States
(12) Patent Application Publication
(10) Pub. No.: US 2002/0197565 A1
(43) Pub. Date: Dec. 26, 2002

(54) Method of transferring photomask patterns

(76) Inventor: I-Pien Wu, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/885,037

(22) Filed: Jun. 21, 2001

(51) Int. Cl. G03F 7/00; G03F 7/20

(52) U.S. Cl. 430/311; 430/313; 430/394; 430/396

(57) ABSTRACT

A method of transferring photomask patterns of a single photomask to a semiconductor wafer. The photomask patterns include at least a first pattern and a second pattern. The semiconductor wafer includes at least a photoresist layer positioned on the surface of the semiconductor wafer. A first exposure process is performed through the first pattern and the second pattern of the photomask to expose a first region and a second region in the photoresist layer, respectively. A second exposure process is then performed through the first pattern and the second pattern of the photomask in order to expose the second region and a third region in the photoresist layer, respectively. The combination of the first pattern and the second pattern in the second region in the photoresist layer is a latent pattern. Lastly, a development process is performed in order to transfer the latent pattern to the photoresist layer.

### BACKGROUND OF THE INVENTION

1. Field of the Invention

The present invention relates to a method of transferring photomask patterns and, more specifically, to a method of transferring photomask patterns of a single photomask to a semiconductor wafer.

2. Description of the Prior Art

To form designed integrated circuits on a semiconductor wafer, a semiconductor manufacturing process is used to manufacture a photomask and to form a designed pattern. A photolithography process, having a specific ratio, is then used to transfer the pattern on the photomask to a photoresist layer on a surface of the semiconductor wafer. Thus, layout patterns of integrated circuits are successfully transferred onto the semiconductor wafer. The photolithography process is a dominant step in the semiconductor manufacturing process.

Please refer to FIG. 1 to FIG. 5. FIG. 1 to FIG. 5 are diagrams of utilizing a photolithography process to transfer photomask patterns 24, 34 onto a semiconductor substrate 10 according to the prior art. As shown in FIG. 1, a top surface of the semiconductor substrate 10 comprises a dielectric layer 12. A plurality of contact electrodes 14 is disposed within the dielectric layer 12. An amorphous silicon layer 16 is set upon the surface of the dielectric layer 12 and the contact electrodes 14. A photoresist layer 18 is disposed on a top surface of the amorphous silicon layer 16. The photolithography process disclosed from FIG. 1 to FIG. 5 is used to define a size and a position of a lower layer storage node of a capacitance in a dynamic random access memory (DRAM).

The photoresist layer 18 is composed of positive photoresist or negative photoresist. In an exposure process occurring during photochemical transformation, if the photoresist layer 18 is composed of positive photoresist, optical beams illuminate the photoresist layer 18 above the top surface of the semiconductor substrate 10 through a photomask pattern, forming a latent pattern in the photoresist layer 18. Then, by way of a development process and a cleaning manufacturing process, the photoresist layer 18 not illuminated by the optical beams remains, forming a hard mask having a shape defined by the photomask patterns. If the photoresist layer 18 is composed of negative photoresist, the photoresist layer 18 not illuminated by the optical beams is cleaned in the development process and the cleaning manufacturing process, such that the remaining photoresist layer 18 on the semiconductor substrate 10 forms a hard mask having a shape defined by the photomask patterns. Further statements in reference to the prior art and the present preferred embodiments will only use a case of positive photoresist in the photoresist layers 18, 48 of the semiconductor substrates 10, 40.

As shown in FIG. 2, the photolithography process utilizes a first photomask 20 to perform a first exposure process. The first photomask 20 is composed of a transparent glass or quartz substrate 22. A surface of the transparent substrate 22 comprises transverse patterns 24 that are formed by a plurality of opaque chromium membranes. When the first exposure process is over, the photoresist 18 on the top surface of the semiconductor substrate 10 is formed into a plurality of transverse patterns without exposure.

As FIG. 3 shows, the photolithography process then utilizes a second photomask 30 to perform a second exposure process. The second photomask 30 is also composed of a transparent glass or quartz substrate 32. A surface of the transparent substrate 32 comprises straight patterns 34 which are formed by a plurality of opaque chromium membranes. When the second exposure process is finished, the photoresist 18 on the top surface of the semiconductor substrate 10 is formed into a plurality of straight patterns without exposure. The plurality of straight patterns and transverse patterns are partially overlapped and vertical.

As shown in FIG. 4, the photolithography process then utilizes a development process and cleaning manufacturing processes to remove regions overlapping portions of the latent transverse and straight patterns of the photoresist layer 18, producing a patterned photoresist layer 19. As shown in FIG. 5, an etching process using the patterned photoresist layer 19 as a hard mask is used to remove regions of the amorphous silicon layer 16 not covered by the patterned photoresist layer 19, up to a surface of the dielectric layer 12. After removing regions of the patterned photoresist layer 19, the remaining photoresist forms a low layer storage node 17.

From FIG. 1 to FIG. 5, the photolithography process divides an original photomask into two portions, the transverse patterns 24 of the first photomask 20 and the straight patterns 34 of the second photomask 30. The photolithography process then utilizes the first and second exposure processes to expose patterns on the first and second photomasks to the photoresist layer 18, respectively. Nevertheless, when operating with multiple photomasks, misalignment problems become very common. Additionally, the different photomasks potentially have errors in materials and manufacture, so that patterns on a photoresist layer can have a quite different size and shape than the size and shape required by the original photoresist layer design.

### SUMMARY OF THE INVENTION

It is therefore a primary objective of the present invention to provide a method of transferring photomask patterns in order to effectively reduce problems of misalignment occurring when using a plurality of photomask patterns.

The present invention discloses a method of transferring photomask patterns of a single photomask to a semiconductor wafer. The photomask patterns include at least a first pattern and a second pattern. The semiconductor wafer includes at least a photoresist layer positioned on the surface of the semiconductor wafer. A first exposure process is performed through the first pattern and the second pattern of the photomask to expose a first region and a second region in the photoresist layer, respectively. Second, a second exposure process is performed through the first pattern of the photomask in order to expose the second region in the photoresist layer. The combination of the first pattern and the second pattern in the second region in the photoresist layer defines a latent pattern. Lastly, a development process is performed in order to transfer the latent pattern to the photoresist layer.

It is an advantage of the present invention that transferring photomask patterns from a single photomask reduces a number of the photomasks used, and economizes the use of time and costs for photomask manufacturing.

These and other objectives and advantages of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 5 are diagrams of utilizing a photolithography process to transfer photomask patterns onto a semiconductor substrate according to the prior art.

FIG. 6 to FIG. 11 are diagrams of utilizing a photolithography process to transfer photomask patterns onto a semiconductor substrate according to the present invention.

FIG. 12 is a diagram of the present invention conception.

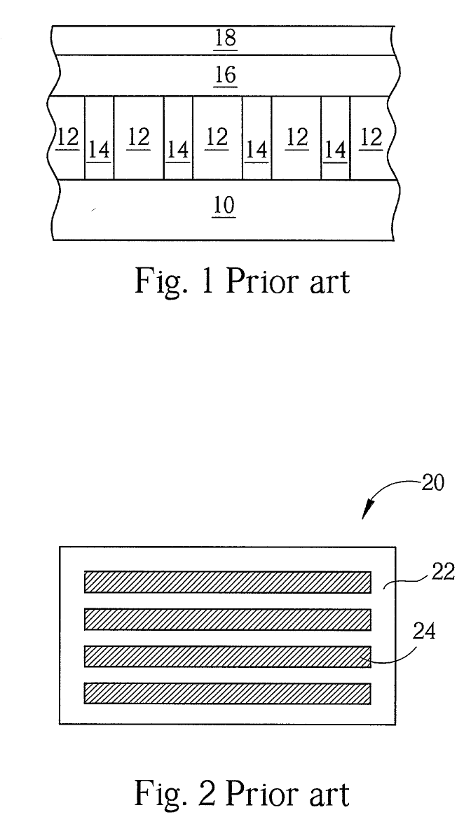

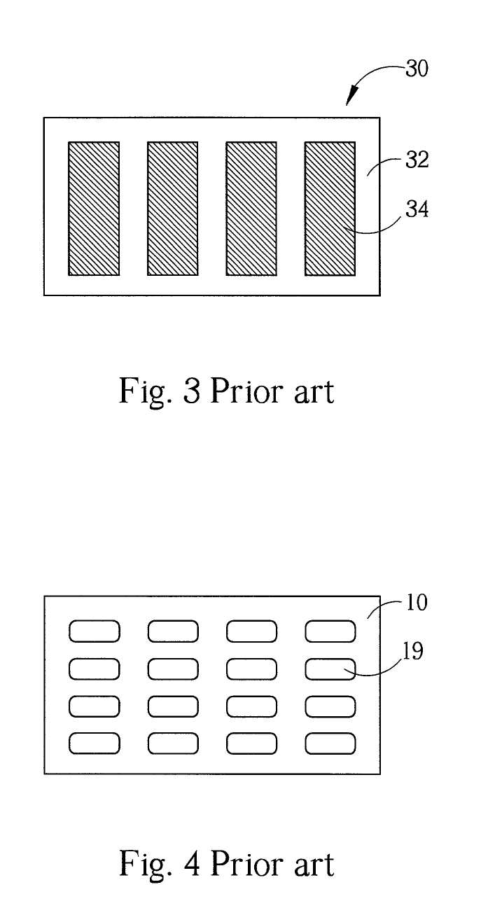

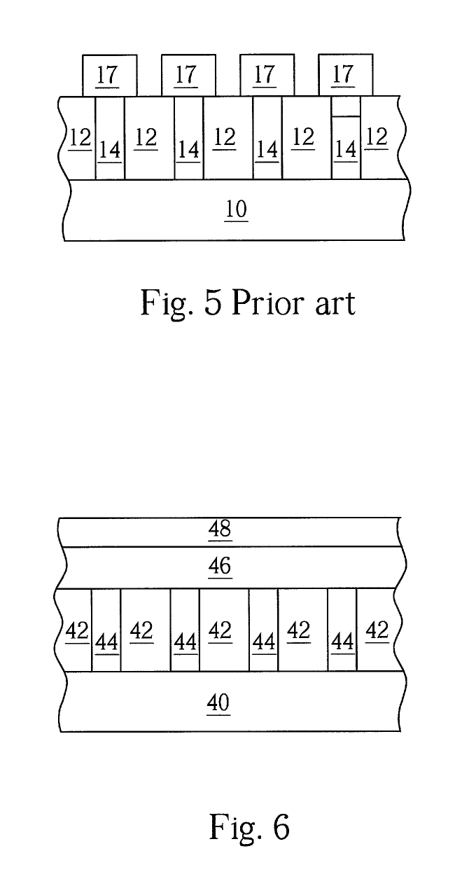

### DETAILED DESCRIPTION OF THE PREFERRED EMBODIMENT

Please refer to FIG. 6 to FIG. 11. FIG. 6 to FIG. 11 are diagrams of utilizing a photolithography process to transfer photomask patterns 52, 54 onto a semiconductor substrate 40, according to the present invention. The photolithography process is used to define a size and a position of a lower layer storage node of a capacitance in a dynamic random access memory (DRAM). As shown in FIG. 6, a surface of the semiconductor substrate 40 comprises a dielectric layer 42 composed of silicon oxide, and a plurality of contact electrodes 44 composed of doped polysilicon, disposed within the dielectric layer 42.An amorphous silicon is set over the surfaces of the dielectric layer 42 and the contact electrodes 44, and a photoresist layer 48 is disposed on a top surface of the amorphous silicon layer 46.

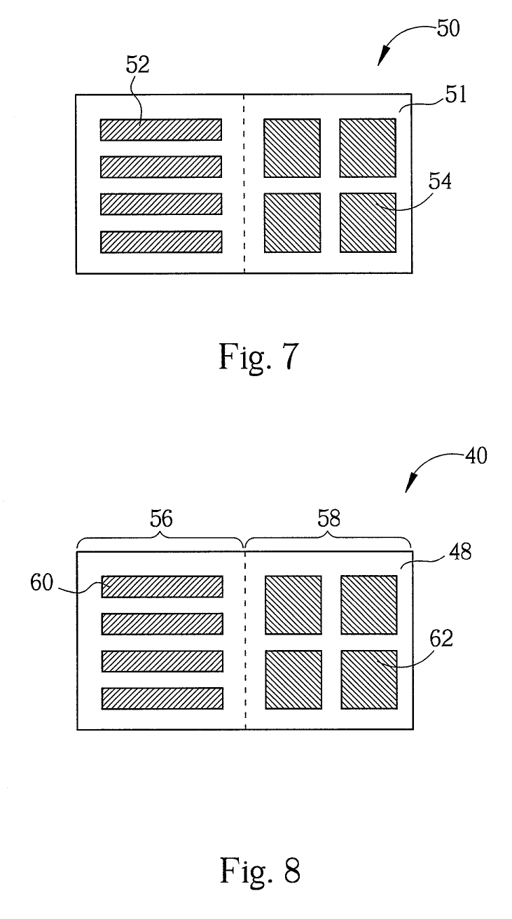

As shown in FIG. 7, a photomask 50 is manufactured before the photolithography process, according to designed integrated circuit patterns. When the patterns of the photomask 50 are manufactured, the present invention provides a pattern separation method, that is, a method of separating multiple patterns of an original photomask, which are different or adjacent, into the same photomask 50. The patterns may then be transferred to the photoresist layer 48, so that the photomask 50 comprises a plurality of transverse patterns 52 and a plurality of straight patterns 54, both formed by opaque chromium membranes and disposed on a transparent substrate 51.

Please refer to FIG. 8. FIG. 8 is a top view of a semiconductor substrate 40 as shown in FIG. 6. The photomask 50 (from FIG. 7) is used to perform a first exposure process in order to expose the photoresist layer 48 to the transverse patterns 52 and the straight patterns 54 on the photomask 50. A plurality of corresponding transverse patterns 60 and a plurality of straight patterns 62 are produced on a first region 56 and a second region 58, which are parallel and adjacent to each other on the photomask 50. The transverse patterns 52 and the straight patterns 54 on the photomask 50 are formed by the opaque chromium membranes. So, when the first exposure process is over, the transverse patterns 60 and the straight patterns 62 formed in the photoresist layer 48 are shadow regions that prevent exposure of regions of the photoresist layer 48.

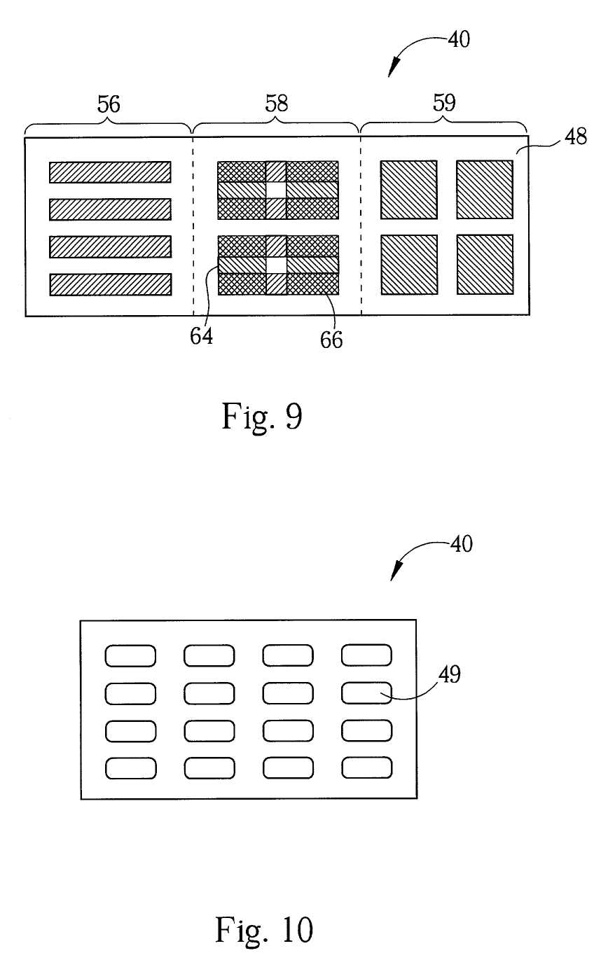

As FIG. 9 shows, the photomask 50 is horizontally moved to perform a second exposure process in order to expose a second region 58 of the photoresist layer 48 to the transverse pattern 52 on the photomask 50. A third region 59 of the photoresist layer 48 is exposed to the straight patterns 54 on the photomask 50. In the second region 58, the transverse patterns 52 formed in the second exposure process and the straight patterns 62 formed in the first exposure process overlap to form a latent pattern 66.

Since the first exposure process and the second exposure process are exposure methods utilizing step and repeat projection, after performing the step and repeat exposure processes, a plurality of latent patterns 66 aligned in an array manner are formed in the photoresist layer 48. The latent patterns 66 are the shadow regions not exposed in the first exposure process and the second exposure process. The portions of the photoresist layer 48 with step and repeat exposing in the first exposure process and the second exposure process form exposure regions 64.

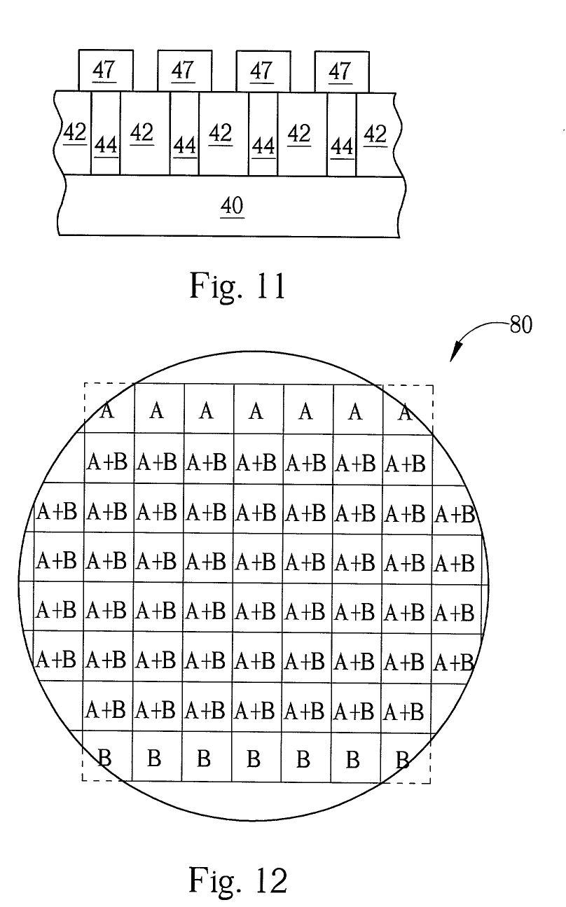

As shown in FIG. 10, after the photoresist layer 48 on the semiconductor substrate 40 undergoes the step and repeat processes, then photolithography and cleaning processeses are performed to remove the exposure regions 64 in the photoresist layer 48, producing a patterned photoresist layer 49. As shown in FIG. 11, an etching process using the patterned photoresist layer 49 as a hard mask is used to remove regions of the amorphous silicon layer 46 not covered by the patterned photoresist layer 49 down to the surface of the dielectric layer 42. After removing the patterned photoresist layer 49, the remaining areas form a low layer storage node 47.

Please refer to FIG. 12. FIG. 12 is a diagram of the present invention conception. A first pattern A and a second pattern B on the photomask are exposed onto the photoresist layer of the semiconductor substrate 80, respectively. The step and repeat exposure processes are then performed, so that the first pattern A and the second pattern B on the photomask overlap in the photoresist layer of the semiconductor substrate 80, in order to transfer latent patterns A+B onto the semiconductor substrate 80.

In contrast to the prior art, the present method of transferring photomask patterns manufactures patterns onto a single photomask, thus reducing a number of photomasks used and economizing the use of time and costs for photomask manufacturing.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of transferring photomask patterns of a single photomask to a semiconductor wafer, the photomask patterns comprising at least a first pattern and a second pattern, the semiconductor wafer comprising at least a photoresist layer positioned on the surface of the semiconductor wafer, the method comprising:
performing a first exposure process through the first pattern and the second pattern of the photomask to expose a first region and a second region in the photoresist layer, respectively;
performing a second exposure process through the first pattern of the photomask to expose the second region in the photoresist layer, the combination of the first pattern and the second pattern in the second region in the photoresist layer being a latent pattern; and
performing a development process to transfer the latent pattern in the photoresist layer.

2. The method of claim 1 wherein the second pattern of the photomask, in the second exposure process, is performed to expose the third region in the photoresist layer.

3. The method of claim 1 wherein the first exposure process is an exposure method utilizing step and repeat projection.

4. The method of claim 1 wherein the second exposure process is an exposure method utilizing step and repeat projection.

5. The method of claim 1 wherein the first region on the semiconductor wafer is parallel and adjacent to the second region on the semiconductor wafer.
